(19) United States
(12) Patent Application Publication
(10) Pub. No.: US 2005/0219083 A1
(43) Pub. Date: Oct. 6, 2005

(54) Architecture for bidirectional serializers and deserializer

(76) Inventors: James B. Boomer, Falmouth, ME (US); Michael L. Fowler, Saco, ME (US)

Correspondence Address: CESARI AND MCKENNA, LLP, 88 BLACK FALCON AVENUE, BOSTON, MA, 02210, US

(21) Appl. No.: 10/802,372

(22) Filed: Mar. 16, 2004

(51) Int. Cl. H03M 9/00

(52) U.S. Cl. 341/100

(57) ABSTRACT

A bi-directional serializer/deserializer is disclosed using a single bi-directional data line and a single bi-directional clock line. Gated buffers are controlled to operate either sending or receiving data, and a phase locked loop provides a clock to shift data out from a shift register. A reference clock is supplied to the PLL and the PLL generates a synchronous bit clock. The bit clock is sent over the clock line in parallel with the serial data bits, and the PLL bit clock is synchronized to the data bits. The receiving system will use the bit clock to serial load a receiving shift register. When a word is received a word clock is available to inform the receiving system. An embodiment of the system sends data to a receiving system using a clock generated at the sending system. Another embodiment receives data but uses a clock that is sent from the receiving system to the sending system, wherein the sending system uses the received clock to generate a clock to send the data and a synchronous clock that is sent back to the receiving system to load the data from the data line.

### CROSS REFERENCE TO RELATED APPLICATIONS

The present application is related to a co-filed application having the owners, the application entitled, BIT CLOCK WITH EMBEDDED WORD BOUNDARY. This application is hereby incorporated herein by reference.

### BACKGROUND OF THE INVENTION

1. Field of the Invention

The present invention relates to data transmission, and more particularly to an architecture and method for converting and sending and receiving parallel word data as a serial data stream—bit by bit, along with a synchronous bit clock.

2. Background Information

FIG. 1 illustrates a known serializer in a block schematic form. A parallel data word 10 is loaded into a buffer register 12 with a word clock 14. The word clock 14 is also fed to a phase locked loop (PLL) 16. The PLL generates a bit clock 18 that loads the shift register 20 and subsequently shifts out the data in the shift register 20 serially bit by bit through a cable or transmission line driver 22. The bit clock 18, that shifts the data out bit by bit, stays synchronized to the bit positions within the word by the PLL. Along with the serial bits from driver 22 a word clock 24 is output via driver 26. The receiver will be able to distinguish the beginning and ending of the serial data stream by referencing the bit stream via the word clock.

FIG. 2 shows a receiver circuit that de-serializes the bits to form words. The serial data 30 is input to a shift registers 32. The word clock 34 is input to a PLL 36 that generates a bit clock 38 that is synchronized to the bit location in a word by the PLL. With this synchronization, the bit clock 38 properly loads the bit stream into the shift register 32. When the word has been received by the shift register 32 (as determined from the word clock), the PLL outputs a clock 40 that load the parallel data in the shift register 32 into a buffer register 42. The word data 44 is in parallel form ready for use in the receiving system.

FIG. 3 shows a complete bidirectional system using the serializers as in FIG. 1 and de-serializers as in FIG. 2. Note that there are 8 data lines and a single clock into each serializer and out from each de-serializer. The data and clock lines between the serializer and the de-serializer are typically differential aignals.

FIG. 4 is a timing diagram shows a generic timing chart that illustrates the serial sending of a framed ten bit word. A word clock 60 is fed to a PLL that generates a synchronous the bit clock 62, the word clock 60 must be occur often enough for the PLL to remain locked. The data bits are loaded into a shift register using one of the clock edges. Then the data bits in the shift register are shifted out serial by the bit clock 62. In FIG. 4 a ten bit word is shifted out.

PLL's (and delay locked loops, DLL's) take up significant room on a die, consume significant power, take significant time to lock, and are complex. It would be advantageous, and it is an object of the present invention, to eliminate at least one of them from a serializer/de-serializer.

A similar operation applies to the receiving of the serial data. In this case the word clock is received and applied to a PLL that generates a synchronous (to the word clock) bit clock that is used to load the data bits into a receiving shift register. Data bits must be stable when the clocks cause the data bits to be sent and to be received. Time delays are designed into such systems to accomplish this, as known in the art. In the case shown, the data bits is sent out synchronously where the lowest order bit of the next word is sent out directly after the most significant bit of the prior word. In other instances the data may be sent out asynchronously, typically using start and stop bit that frame the data bits. In both the synchronous and asynchronous cases system means must be employed, as are well known in the art, to prepare the sender and the receiver to properly send and receive the data. Also, systems are arranged to send data then after sending receive data; while other systems can send and receive simultaneously. The former referred to as half duplex and the latter as duplex. Again system designers understand the limitations and requirements of such systems to properly send and receive data.

FIGS. 1 and 2 contain a buffer register that holds the word to be sent or the word just received. The buffer allows nearly the entire time for a word to be sent or received before the next word is loaded. The logic and the timing to accomplish these tasks are well known. However, the buffer registers are not required, and if not used then the word to be sent and the word received must be processed during a bit time. Again such designs are well known in the art.

In general, transferring serial data offers an advantage that the cable running between the sending and receiving systems need only have a few signal (one data and one clock) carrying wires (and, of course, one or more return lines). In contrast if the data were sent over the cable in parallel, line drivers for each bit in a word along with a clock driver creates large currents and therefore significant system noise and power dissipation.

### SUMMARY OF THE INVENTION

Objectives and advantages are achieved with the serializer/de-serializer of the present invention. A bi-directional data line and a bi-directional clock line are provided that are buffered from the serializer/de-serializer electronics so that the data and clock signal flow directions may be reversed. A parallel data word is loaded into a shift register and a bit clock shifts the data out over the data line. A clock is generated or is received from a computing system that is input to a phase locked loop (PLL) that, when locked, produces the bit clock. The bit clock is also sent out over the bi-directional clock line coincident and synchronized with the data bits being sent. The synchronous bit clock is arranged with an edge that occurs while the bit data is stable so it can be used by a receiving system to load the data bits.

The PLL is arranged so that it may accept a bit clock from the bi-directional clock line and produce therefrom a clock signal arranged for loading data from the data line into a shift register.

In preferred embodiments, a REF clock is used to lock the PLL's, a WORD clock latches data into buffer registers. The data lines are bidirectional as is the bit clock line. In preferred embodiment, there is an overall master or controller that handles the data and clock direction reversals so that information is not lost. In other preferred embodiment, the synchronization between the sender and the receiver to turn around the data/clock signal directions can be handled by control/status line or lines between the two. Protocols may be developed by those skilled in the art to ensure that proper control of the communications between the sending and receiving systems. For example, if busy was not asserted, the system wanting control would assert busy. At some random time, the system would dis-assert busy in case the prospective receiver asserted busy at the identical time. If the busy signal remained asserted, that side would delay taking control until the other side finished and dis-asserted busy. If the busy signal went dis-asserted, that side would re-assert the busy and send its message. Information being transferred would typically have error check system, so that if there was contention remaining on the communication improper information would be detected and the transfer re-tried at some later time. Such techniques and systems are well known in the art.

It will be appreciated by those skilled in the art that although the following Detailed Description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

The invention description below refers to the accompanying drawings, of which:

FIGS. 1 and 2 are block diagram schmeatics of a prior art serializer and de-serializer;

FIG. 3 is a system block diagram fo a prior art duplex system;

FIG. 4 is a representative prior art timing chart;

FIG. 5 is a block diagram schematic of an embodiment of the present invention;

FIG. 6 is a mode table;

FIGS. 7 and 8A are data bit timing charts;

FIG. 8B is a schematic of a logic circuit that detects word boundaries in the bit clock;

FIG. 9 is an illustration of a bus hold circuit;

FIG. 10 is a schematic of a gated transmission line termination;

FIG. 11 shows a wired or status bit;

FIGS. 12, 13, 14 and 15 illustrative different operation applications of emdoiments of the present invention;

FIGS. 16 and 17 illustrate simplified bi-directional applications of embodiments of the present invention;

FIGS. 18, 19A and 19B are timing diagrams showing various placements of the word boundaries;

FIG. 20A is another timing diagram; and

FIG. 20B is a circuit block diagram that implements the embodiment of FIG. 20A.

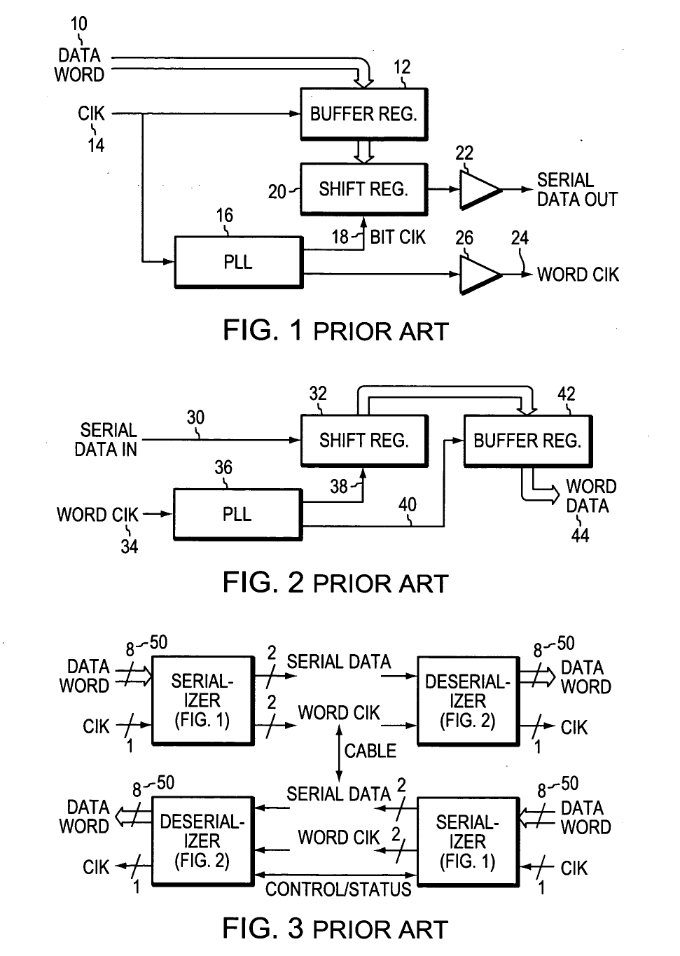

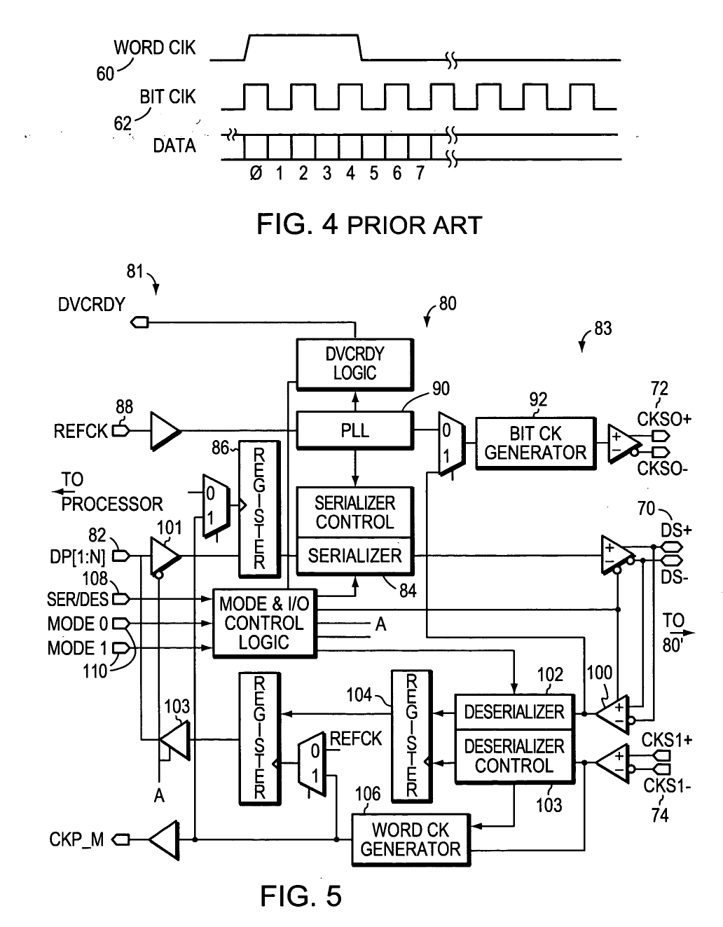

### DETAILED DESCRIPTION OF AN ILLUSTRATIVE EMBODIMENT

FIG. 5 is a block diagram that indicates the operation at a high, functional level showing a serializer/de-serializer 80. The left side 81 of FIG. 5 show electrical contact points arranged to be connected to a processor or computer bus system while the rights side 83 of FIG. 5 is arranged to connect to a transmission cable, or the like, that connects to corresponding pins on serializer/desrializer 80′ that is similar to the serializer/de-serializer 80. The data lines (DS+, DS−) 70, the clock out lines (CKSO+, CKSO−) 72 and the clock in lines (CKS1+, CKS1−) 74 are typically differential pairs as shown. Line drivers and receivers for differential pairs are well known in the art. Moreover, in particular applications the clock in and clock out lines may be joined together so that only a single data pair and a single clock pair are output to connect to another serializer/de-serializer 80.′ These differential pairs will be referred to as CKSO, CKS1, and DS unless a specific reference is clearer referring to the individual signals.

When device 80 is sending out data, parallel data 82 from a processor bus is loaded into a register 86 that holds the data for loading into a shift register serializer 84. REFCLK 88 drives and synchronizes the PLL 90 that generates a synchronous (to the REFCLK) bit clock 92 that is sent out via 72. A receiver system 80′ is arranged to accept the bit clock 72 and clock in the serial data bits are they arrive on the data lines 70. A signal from the PLL also drives the serializer control and serializer 84 causing the bits to be shifted out 70 synchronized to the bit clock 72. An edge of bit clock 72 occurs while the data bits 70 are stable allowing the receiver to reliably clock in the received data 70.

When the serializer/de-serializer 80 is arranged to receive data via the differential receiver 100. The received clock signals 74 are used to clock in the data into the de-serializer 102. When a full word is received the de-serializer control 103 loads the word into the register 104. A word clock is generated 106 informing the processor system, connected to 81, of the receipt of a complete word.

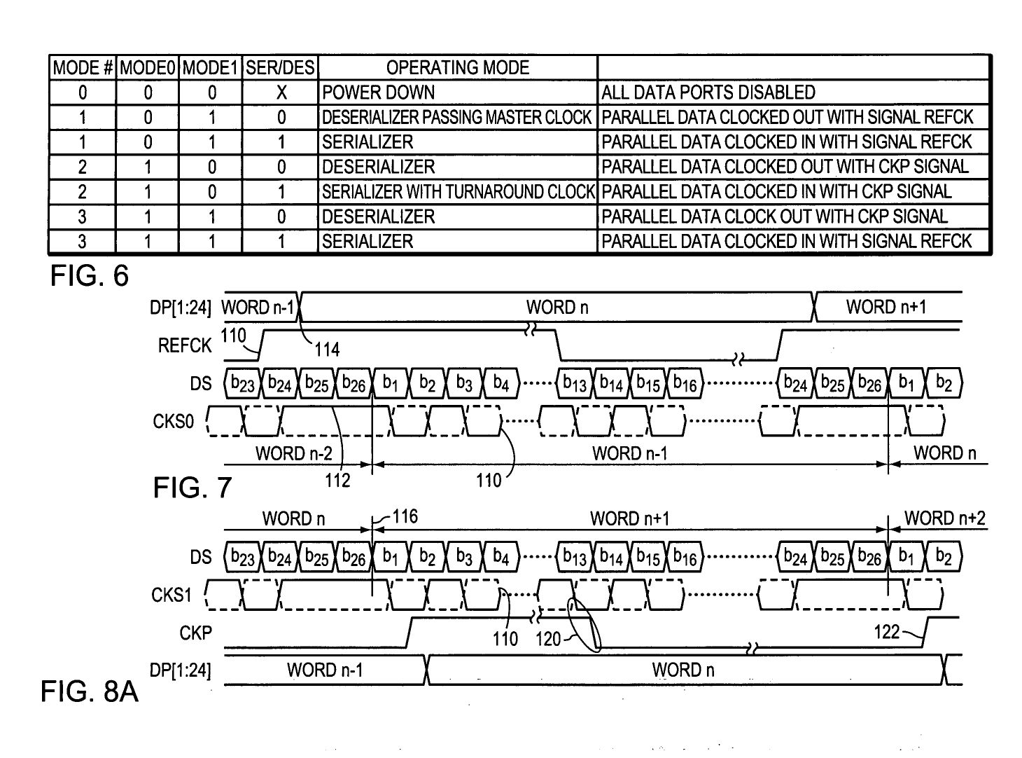

The SER/DES signal programs the device 80 to be a sender when high or a receiver when low. These signals may be wired high or low or controlled by the processor. The MODE0 and MODE1 110 inputs along with the SER/DES signal determine the operating characteristics of the device 80, that are shown in FIG. 6. Although the following mode control is described, other approaches to controlling the serializer/de-serializer can be used. For example, in simplest form control is maintained by the SER/DES signal alone, or a separate control port could be used.

FIG. 5 shows a serializer that may be implemented as a shift register, or by multiple shift registers, or by multiple shift registers outputting data via multiplexer. A serializer may also be one or more multiplexers that select and output each bit of a word from a holding buffer register. Correspondingly, a de-serializer may be formed by s shift register and/or multiple multiplexers and a holding register.

The following description includes FIG. 5 with respect to each of the logic conditions shown in FIG. 6 and the timing of FIG. 7.

FIG. 6 mode # 0 is a power down condition where the device is disabled.

In mode #1 or # 3 with SER/DES signal high, the device operates as a serializer. Parallel data 82 is latched into register 86 on the rising edge of REFCK, and clocked out serially 70 via 84. CKSO 72 is synchronously generated with the serial data signals. In one embodiment WORD n−1 of twenty four data bits, see FIG. 7—b1-b24, are first loaded on the rising edge of REFCK into the register 86. A word boundary is formed in the bit clock CKSO 112 (FIG.&). Bits b25 and b26 are added between the prior word sent (WORD n−2) and WORD n−1. Then four bit clocks after the rising edge of REFCK, b1 of WORD n−1 is synchronously clocked out immediately after the end of the two bit word boundary 112. Data bits b25 and b26 fill in the space between the two words being sent.

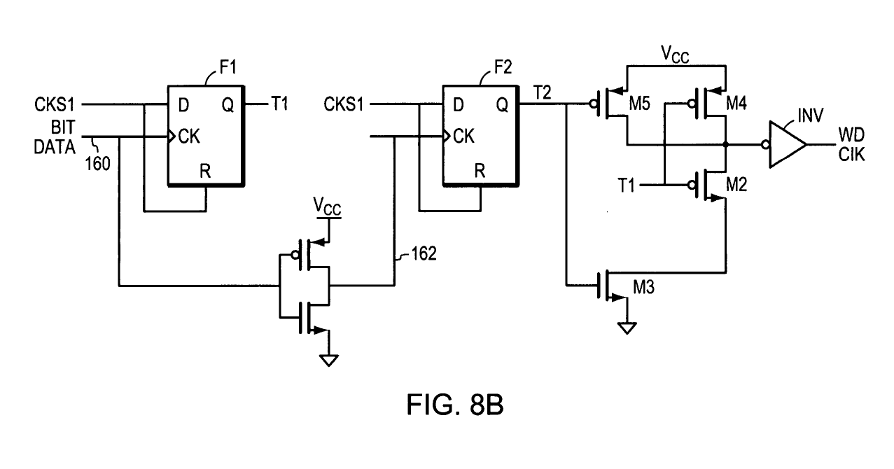

In mode #3 when SER/DES signal is low the device operates as a de-serializer, the timing chart FIG. 8 applies. Data is received at 70 on FIG. 5, synchronously with the bit clock CKS1. The received data bits are loaded into the de-serializer and a word clock CKP generated. The falling edge of the bit clock CKS1 will initiate the falling edge of the CKP 120. The rising edge 122 of CKP will occur about twelve bit time later (one half of a twenty-four bit word) later. Parallel data will appear about 2 bit clock times after the risign edge of CKP. In parallel an optional REFCK can be provided as a reference the PLL. The PLL will generate a bit clock transmitted out as CKSO, if needed.

In mode #2 with SER/DES signal low the device is a de-serializer. Data (DS) is received synchronously with the received bit clock CKS1. The data is de-serialized, the bit b25 and b26 in the word boundary are stripped and the resulting parallel word may be retrieved by the processor on data lines DP 82 of FIG. 5. The bit clock CKS1 will also generate the CKP word clock, and CKSO is held low.

In mode #2 when SER/DES signal is high the device deserializes received data synchronously with the received bit clock CKS1. The data in the word boundary data, b25 and b26, is stripped by the de-serializer control 103 (FIG. 5) from the twenty-four word data bits. The word data is then made available on on the parallel port 82 (FIG. 5) for the processor. The word clock CKP is also available to the processor.

In mode #1 with SER/DES signal low the device acts as a bidirectional de-serializer. In this operation REFCK, via the PLL sends out the clock CKSO to be used to clock the serial data by the upstream sending device. De-serialized data is synchroouly received on the DS and CKS1 ports. The data in the word boundary is stripped, as before, and the data word is synchronously with the REFCK sent out on the parallel port DP for the processor to accept.

Operation of a system of FIG. 5 with bi-directional data and clock lines will be useful at lower system speeds. When higher speed are necessary, the data and the clock lines may be cabled independently so that there are two data lines each transferring unidirectional data in opposite directions and separate unidirectional clock lines with clocks traveling in opposite directions. The serializer/deserializers 90 and 90′ may also be operated with two clock lines but a single bi-directional data line, or a single bi-directional clock line and two unidirectional data lines, although this arrangement.

The input buffers 101, FIG. 5, are low voltage CMOS circuits with a nominal threshold of about ½ the powering voltage, VDD, that are operational only when the device 80 is a serializer. They are held off to conserve power when the device is a de-serializer.

The output buffers 103 are three state circuits that will source/sink 2 mAmps at 1.8V that are active only when the device 80 is de-serializer. They are held in the high Z state when the device 80 is a serializer.

CMOS devices with low, 2 mA, drive currents were used throughout embodiments of these circuits. However, TTL or LV_TTL or even differential signaling could be used and the drive current could be of any logic type, from very low currents (sub-mA's) o very high currents (100's of mA's).

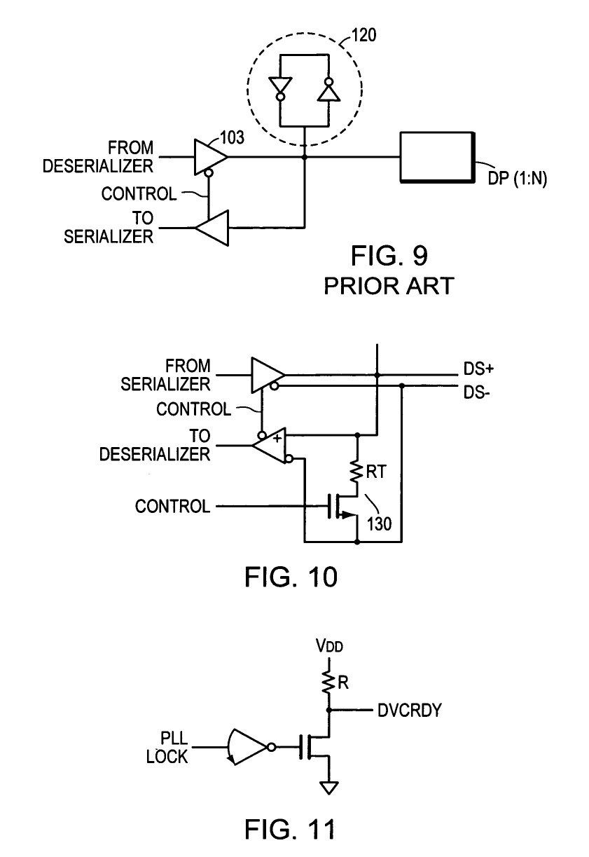

FIG. 9 shows a gate hold circuit, known in the art, that maintains the last state of the DP lines when the driver 103 goes high-Z. There is a gated differential line termination 130 shown in FIG. 10. When the device 80 is a de-serializer received data on the DS lines is terminated with a series resistor and one CMOS transistor. The value of the resistor RT and the on resistance value of the CMOS transistor are selected to match the transmission line characteristic impedance.

Referring back to FIG. 5, there is a DVCRDY signal available to the processor. When the PLL is locked this signal becomes true. FIG. 11 shows this signal available as a wired OR. Since a PLL may take some time to become locked, this signal can be used by the processor to ensure that the device 80 is ready.

Referring back to FIGS. 7 and 8A, there is shown a bit clock CKSO and CKS1, respectively. In each case at the sending word boundary 114 of FIG. 7, CKSO remains high, and data bits b25 and b26 are sent over the data lines. In FIG. 8 at the word boundary 116 the CKS1 is high and data bits b25 and b26 are received. Please note that in this discussion the CKSO and CKS1 go high during the word boundaries, but a system could be implemented with them going low, as would be known to those in this art. When not at a word boundary, the clocks in both FIGS. 7 and 8A provide an edge during each data bit time. The data bits are sent or retrieved during both the rising and the falling edges of the bits clocks. The system that is sending or receiving data will detect the word boundary by recognizing that there was no clock pulse between two data bits. In FIGS. 7 and 8 the missing clock pulse means that a clock edge is found at the end of b24 (to load b24), but there is no clock edge for b25 and none for b26, there is missing two edges of a full clock pulse. The data bits at the word boundary are arranged so that there will always be an edge between bits b25 and b26, so if no clock pulse is detected between any data transition of any two bits, those bits must be the word boundary bits, b25 and b26. The logic implementation to perform this detection is well known in the art. One design where say the clock stayed high during the word boundary, would have a flop that toggles on each clock falling edge. In one preferred embodiment, the first boundary bit will always be arranged to have a transition edge with respect to the previous data bit, and then there will be another logic transition between the two boundary bits. So if the previous data bit is a logic 1, the succeeding boundary bits will be logic 0,1; and if the previous data bit is a 0, the boundary bits will be 1,0.

When a system is sending data, the sender knows where the word boundaries are, so deleting a clock pulse is straight forward, but not so when receiving serial data. FIG. 8B shows one logic circuit that can be used to detect a missing clock pulse during a data bit transition (the sender always requiring a transition of the data stream during the word boundary. F1 and F2 are D type flip flops with the received bit data 160 fed to the clock input of F1 and the bit data inverted 162 fed to the clock of F2. The D inputs and the resets of both flops are connected to the received bit clock CKS1. CMOS transistors M2, M3, M4, and M5 are arranged as an AND with an inverter INV to form a NAND circuit.with inputs ti and t2 from the flop outputs, and an output is the word clock WDCLK. In operation when CKS1 is low both flops are reset and t1 and t2 are low. So the WDCLK is low. When CKS1 is high and data transitions occur either t1 or t2 will go high but not both. On the next low going CKS1 edge both flop outputs will again go low. When CKS1 is high for two consecutive bit times and data toggles high and low during this period, both t1 and t2 will go high and via the NAND WDCLK will go high. On the next falling edge of CKS1, WDCLK will go low.

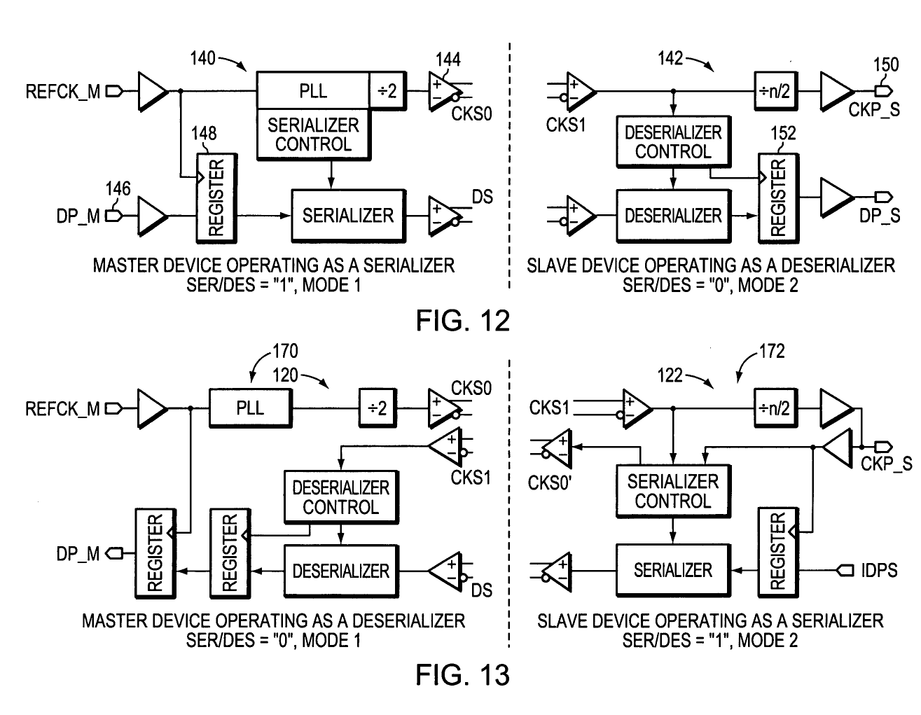

FIGS. 12, 13, 14 and 15 show typical applications of the device illustrates a master/slave operation of two devices as shown in FIG. 5.

In FIG. 12 illustrates a typical serializer/de-serializer pair operating as a master/slave with unidirectional data transfers. One device 140 (80 in FIG. 5) is arranged in mode #1 with SER/DES signal set high, the device 140 acting as a serializer. Item 140 acts as the master and is that portion of the device (80 in FIG. 5) primarily operating in this mode. Item 142 is the slave operating as a de-serializer receiver of the data from 140. Device 142 is arranged in mode #2 with SER/DES signal set low. REFCK_M is a word clock input to the PLL that generates a bit clock 144 with an embedded word boundary. The bit clock The bit clock is received by 142 via the CKS1 port as shown. Item 140 receives parallel data 146 from a processor via DP_M port that is loaded into the register 148. That data is serialized and sent out synchronously with the bit clock CKSO via the DS line. The CKSO and the DS are arranged so that each edge of the CKSO is used to load data at the receiver 142.

The slave 142 accepts the CKSi and generates a word clock CK_P 150. The de-serialized DS data stream is loaded into the register 152 and made available on the DP_S port together with the word clock CK_P so that the receiver processor can retrieve the sent data.

FIG. 13 illustrates a master/slave operation where the clock is generated at the master but data flows from the slave to the master. Device 170 is arranged as the master but a de-serializer. Device 170 delivers a bit clock CKSO via the PLL and a divider, but with no word boundary. The master receives a bit clock CKS1 from the slave, but a the slave has introduced the word boundary missing clock pulse in the cCKSO′ via the serializer control. Device 170 receives the serial data, parallelizes it and presents the parallel data to the processor bus DP_M with the REFCK_M. The slave 172 serializes parallel data stored in the register 174 by the CKP_S.

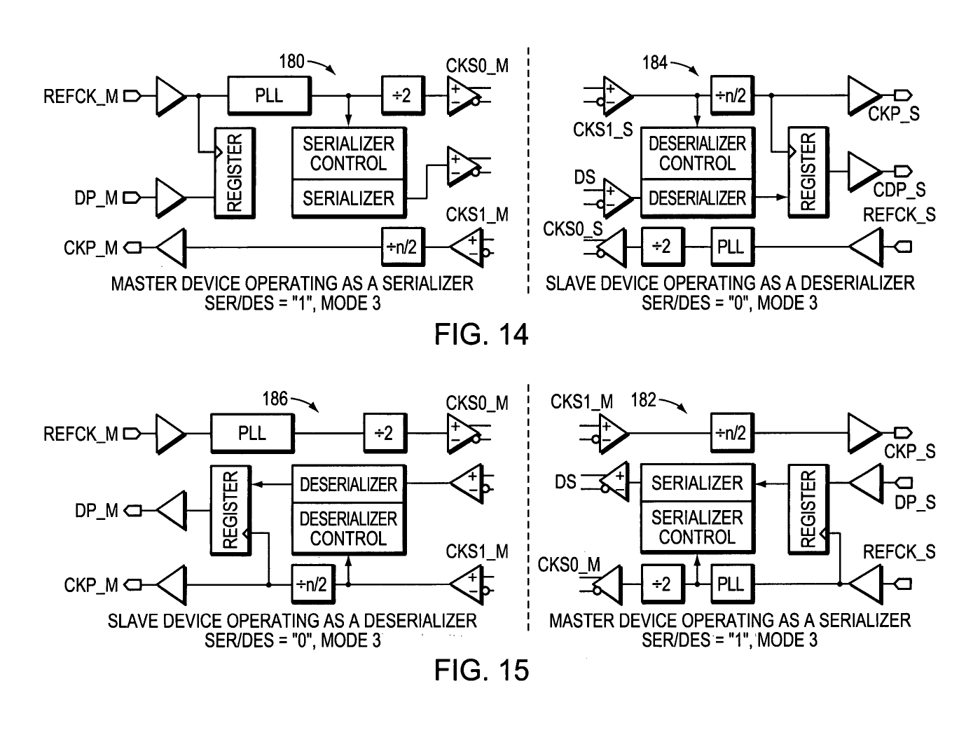

FIGS. 14 and 15 illustrate bidirectional data with PLL's running on both the master and slave device. The clocks running on either side of the serial transmission line are completely independent from each other. In each case the master 180 in FIGS. 14 and 182 in FIG. 15 are placed into mode #3 and each accepts the REFCK and generates a bit clock with an embedded word boundary. Parallel data is received as described above and sent synchronously with the bit clocks to the slave devices. In this application the master accept from the slave a bit clock with an embedded word boundary and generate a word clock CKP_M. The slave devices 184 and 186 operate as de-serializers and accept the bit clock with the embedded word boundaries. The slaves generate the word clock CKP_S(M) and de-serialize the data stream using the CKS1 clocks. Parallel data is written onto the DP_S port with the CKPS(M) clock. The slave also generates a free running bit clock based on the REFCK signals and transmits this bit clock to the master.

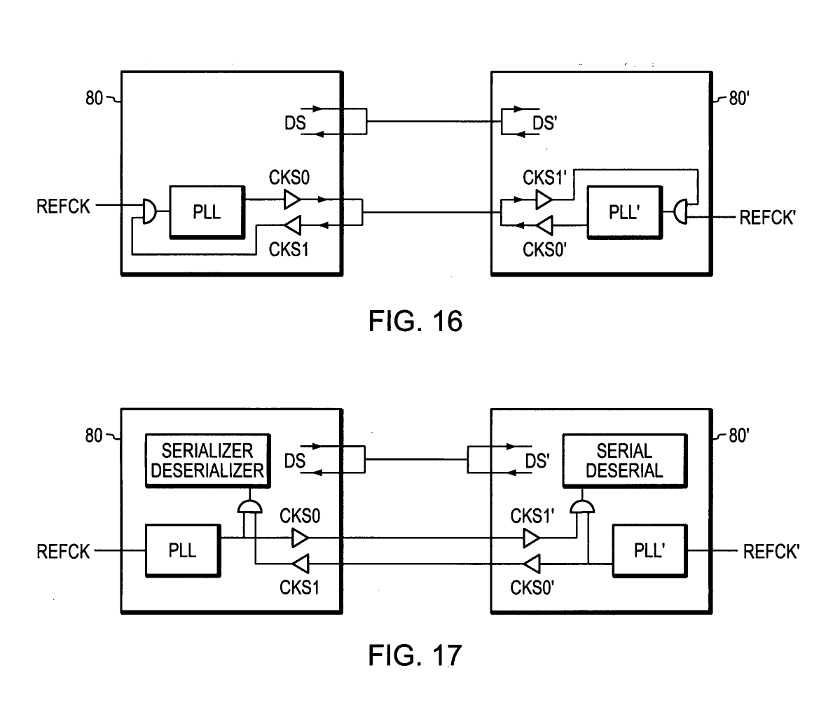

FIG. 16 shows on arrangement where there is a single data line and a single clock line between two devices 80 and 80′ each similar to that in FIG. 5. Here there is bidirectional data transfer where both data and clocks must be turned around to implement the bidirectional data transfers. The data transfers are half duplex and the modes and control of the items 80 and 80′ must be arranged to accommodate the data reversal. The PLL's must remain locked be locked before data can be transferred. Control of 80 and 80′ via the mode and clocks as shown in FIG. 6 can be implemented as is known by system designers in this art field. For some applications this embodiment may be inappropriate principally due to the PLL turn around time that may take hundreds or thousands of REFCK cycles.

As mentioned above, control of turning around the data and clock lines may involve protocols and additional control or status lines between a sender (serializer) and a receiver (de-serializer) that may also include a master aware of conditions or status at both ends of the data and clock lines. Also, in the case of episodic data transfers, the PLL's remain locked by feed them word or reference clock signals. The bit clock on the transmission lines may remain cycling but without any word boundary included. Alternatively, the bit clock may remain in a low where the protocol requires a word boundary to be a bit clock high together with a data line transition so that no word boundary can be detected. Logical combinations may be used as practitioners in the art will be aware. In situations where no data has been transferred in some time, when the bit clock is always being sent, the sending system will begin a data transfer by sending, for example, eight bits of data followed by the word boundary. The receiver will receive the serial data not knowing if it has received data or not, if no word boundary is detected the eight bits of data are deemed to be not useful. In this case the next bit is shifted into the receiver shift register and the earliest bit is shifted out and lost. This continues until a word boundary is detected at which time the receiver stores the prior eight bits as it is now deemed to constitutes a word. Again practitioners in the art will understand and be able to institute other techniques that are well known in the art.

FIG. 17 is similar to FIG. 16 except that there are two separate clock lines between device 80 and 80.′ This set up dispenses with any PLL turn around time and so can be used in applications that cannot use the system of FIG. 16. Both 80 and 80′ are arranged for acceptance of parallel data from their respective processors and both are arranged to provide parallel data to those processors, as described earlier. In this implementation when either 80 or 80′ are acting as a de-serialzer, the PLL in the de-serializer need not be used. The transferred bit clock is used to directly load the de-serializer as shown in FIG. 13.

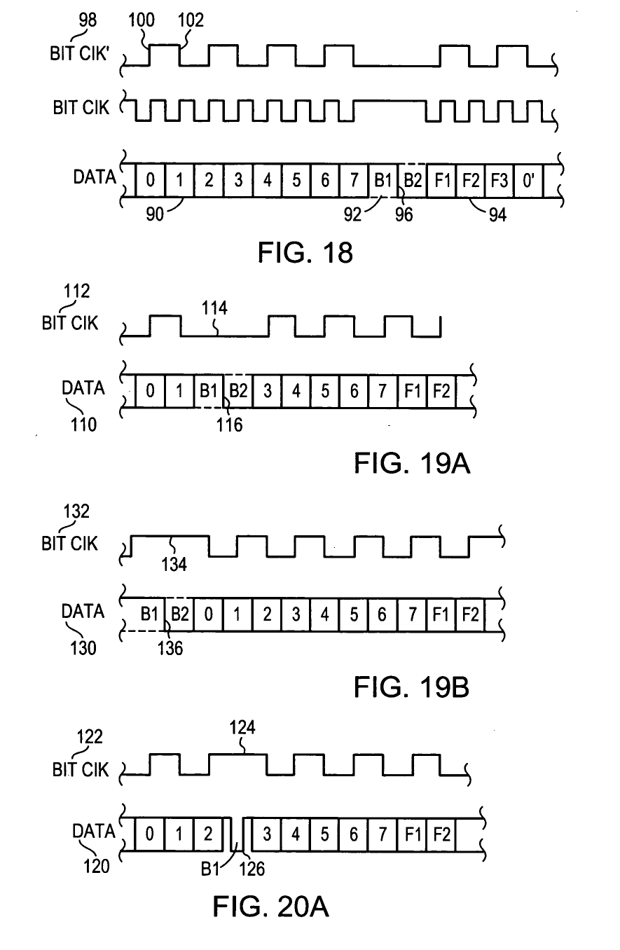

FIG. 18 shows a bit clock scheme with word data bits 90, boundary bits 92, and filler bits 94. In this case a different number of filler bits may be sent between different words. Also, shown is an embodiment where the data is latched on the rising edge only of the bit clock. Of course a similar design may be used where the falling edge only of the clock is used to identify the data of filler bits, F1, F2, etc. The bit clock, in such a case as seem from the drawing running at twice the data clock frequency. Eight word data bits, 0-7, are stable during the rising edge of the bit clock as sent or as received. In this case the word boundary bits B1 and B2 are shown with a concurrent data bit edge 96 occurring while the bit clock is high. Please note that the bit edge 96 may be high to low or low to high, and it may shift between these two edge directions during subsequent data words. The logic must detect either type of edge. This is the word boundary as described before. However, in this case, there are filler bits F1, F2, and F3 that occur prior to the next data word bit 0.′ The boundary bits are serially clocked out by a second clock, synchronous with the bit clock, except the second clock has edges suitable to shift out or select (say via a multiplexer) the two boundary bits. This second clock must be present in the other embodiments, since, as shown, the bit clock has no edges during the boundary bit times. So if the last data bit is a logic 1, the first boundary bit will be a logic 0 and the next boundary bit a logic 1. Correspondingly, if the last data bit is a logic 0, the boundary bits, in order, will be logic 1, 0.

Another embodiment shown in FIG. 18 as BIT CLK′ 98 provides for latching the data bits on either a rising 100 or a falling 102 bit clock edge and thereby not to have a double frequency data clock. Logic implementation to accomplish this is known in the art. In this case the BIT CLK′ is at a constant low 104 during the word boundary. The bit clock at the word boundary can be either high or low, and the polarity of the bit clock may be high for one word and low for another within the same data word stream.

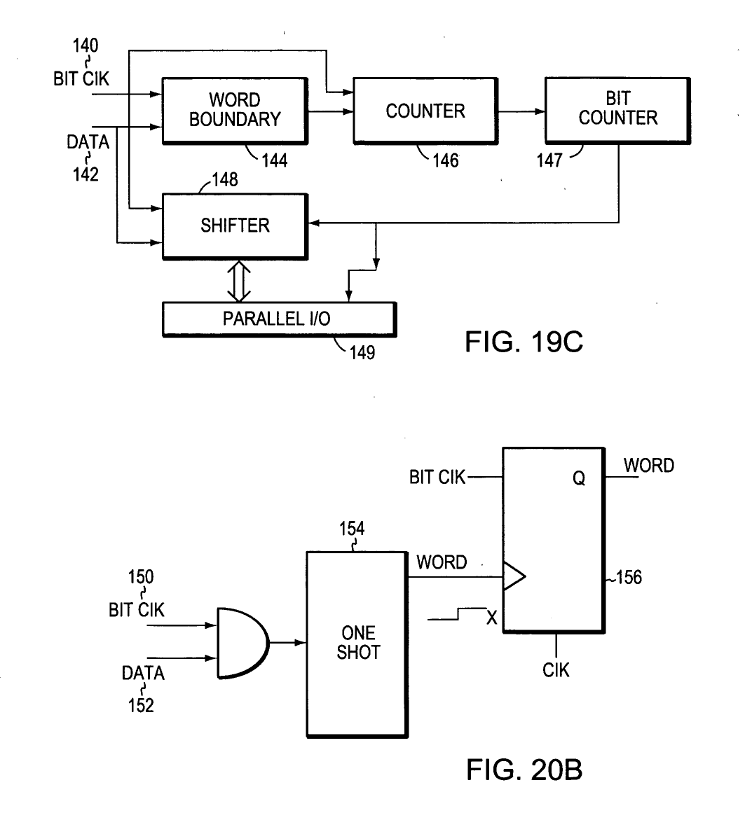

FIG. 19A shows another preferred embodiment of the invention. In this case the word boundary bits B1 and B2 can appear within the data bit stream 110 defining one data word. Here the word boundary bits are between the second and the third data bits. The receiver knows where the boundary bits will be placed and stores the previous received data bits up to the where the boundary bits might appear. In FIG. 19A, the receiver at least always stores the first three bits, and if the next two define a word boundary, then the first three and the next five are retained at the receiver to constitute an eight bit word. The determination of the word boundary is as described above where the bit clock 112 is constant 114 during two boundary bit times and the boundary bit transition 116 during the constant bit clock defines a word boundary. FIG. 19B shows the data bit stream 130 and the bit clock 132 with the word boundary bits B1 and B2 at the beginning of the data word. Here the constant value bit clock during the boundary bit transition 136 defines the word boundary as discussed before.

FIG. 19C shows one implementation of circuitry that will detect the word boundary at the beginning of a word. The bit clock 140 and data 142 are fed into circuitry 144 that detects the combination indicating a word boundary. When so determined, a counter 146 counts the number of bit clocks that equal a data word. The data is clocked into a shifter 148 until the correct number of data bits have been loaded. The bit counter 149 holds the word now in the shifter 148 and informs a computing system that it may read the data word from the parallel I/O port 149. When the boundary bits are place at the beginning of a data word, there, by definition, will always be filler bits preceding the boundary bits. Here, as above, there will be a forced logic transition between the last filler bit and the fist boundary bit. So, as above, if the last filler bit is a logic 1, the boundary bits in order will be logic 0, 1; and if the last filler bit is a 0, the boundary bits, in order, will be logic 1, 0.

FIG. 20A shows an embodiment where only one boundary bit is used. In this case there is a missing bit clock edge 124 transition during the boundary bit time B1 between data bit 2 and data bit 3. Here the sending system during the single bit word boundary causes a double frequency to appear during that boundary bit time 126. Please note that although the pulse 126 is negative going a positive going pulse may be used. Again as with the above described embodiment, the bit clock being sent out defines the bit times for the receiving system, another corresponding clock is used to actually output the bits, usually from a shift register, but also from a multiplexer design.

FIG. 20B shows one simple approach to detecting the double data bit during a high bit clock. In this embodiment, bits are determined on each edge of the bit clock. In this case a word boundary is the B1 of FIG. 20A during a high bit clock 122. An AND condition of a high bit clk and a false data signal 152 produce a trigger on the leading edge of the false data signal going high to the one shot 154. This one shot outputs a pulse that is set to last until the end of the bit time. If the bit clock is still high then the d-type flop 156 is set and WORD is true. This indicates that a word boundary has been received. During regular data time when data and bit clock combined to trigger the one shot the bit clock will be low at the end of the data bit time and the flop 156 will not be set. Of course other designs where the bit clock is a constant low and where the data double frequency is a low with a high pulse, opposites of the signals shown in FIG. 20A is are within the skills of practitioners in the art. Also, designs where the bit clock is a double frequency as discussed above are known to those skilled in the art.

It should be understood that above-described embodiments are being presented herein as examples and that many variations and alternatives thereof are possible. Accordingly, the present invention should be viewed broadly as being defined only as set forth in the hereinafter appended claims.

1. A serializer arranged to accept a data word from a computing system and to send the data word out bit by bit, the serializer comprising:
means for serially outputting the data word via a data line of an output port, the means for serially outputting having a control input; and
a first bit clock connected to the control input wherein the data bits are serially sent out, and wherein the first bit clock is synchronized to the define the individual bits being sent out, and wherein the first bit clock is sent out via bit clock lines of the output port, the bit clock in parallel with the data bits.

2. The serializer of claim 1 further comprising means for obtaining the data word from a bi-directional data bus of the computing system.

3. The serializer of claim 1 further comprising means for sending a word boundary comprised of a combination of signals on the bit clock and the data lines of the serial port.

4. A deserializer arranged to receive a data word bit by bit and present the data word to a computing system, the deserializer comprising:
means for serially receiving the data word bits from a data line of a serial input port, the means for serially receiving data having a control input; and
a bit clock signal synchronized to define the individual bits being received, the bit clock received from a bit clock line of the serial input port, and wherein the bit clock is connected to the control input wherein the data word bits are serially received.

5. The deserializer of claim 4 further comprising means for sending the received data word to the computing system is via a bi-directional data bus.

6. The deserializer of claim 4 further comprising means for receiving and detecting a word boundary comprised of a combination of signals on the received bit clock line and the data line.

7. A serializer/deserializer, the serializer portion arranged to accept a first data word from a computing system and to send the first data word out bit by bit, and the deserializer portion arranged to receive a second data word bit by bit and present the second data word to the computing system, the serializer/deserializer comprising:
means for serially outputting the first data word via a data line of a serial port;
the means for serially outputting having a control input;
a first bit clock connected to the control input wherein the first data bits are serially sent out, and wherein the first bit clock is synchronized to define the individual bits being sent out, and wherein the first bit clock is sent out via a bit clock line of the serial port, the first bit clock in parallel with the data bits;
means for serially receiving second data word bits from the data line of the serial port, the means for serially receiving having a second control input; and
a second bit clock signal synchronized to define the individual bits being received, the second bit clock received from the bit clock line of the serial port, and wherein the second bit clock is connected to the second control input wherein the second data word bits are serially received.

8. The serialzer/deserializer of claim 7 further comprising means for obtaining the first data word from a bi-directional data bus of the computing system, and means for sending the received second data word to the computing system is via the bi-directional data bus.

9. The serializer/deserializer of claim 7 further comprising means for forming and sending a first word boundary comprised of a combination of signals on the bit clock line and the data line of the serial port, and means for receiving and detecting a second word boundary comprised of a combination of signals on the bit clock line and the data line of the serial port.

10. The serializer/deserializer of claim 7 further comprising means for controlling the sending and the receiving of data and bit clock over the serial data port.

11. A process for serializing that is arranged to accept a data word from a computing system and to send the data word out bit by bit, the process comprising the steps of:
serially outputting the data word via a data line of an output port;
controlling the serial outputting with a control input;
connecting a first bit clock to the control input wherein the data bits are serially sent out, and wherein the first bit clock is synchronized to define the individual bits being sent out; and
sending the first bit clock out via bit clock lines of the output port, the bit clock in parallel with the data bits.

12. The process of serializing of claim 11 further comprising the step of:
obtaining the data word from a bi-directional data bus of the computing system.

13. The process of serializing of claim 11 further comprising the step of:
sending a word boundary comprised of a combination of signals on the bit clock and the data lines of the serial port.

14. A process of de-serializing that is arranged to receive a data word bit by bit and present the data word to a computing system, the process comprising the steps of:
serially receiving the data word bits from a data line of a serial input port;
controlling the serially receiving data with a control input;
receiving a bit clock from a bit clock line of the serial input port, the bit clock synchronized to define the individual bits being received; and
connecting the bit clock to the control input wherein the data word bits are serially received.

15. The process of de-serializing of claim 14 further comprising the step of:
sending the received data word to the computing system via a bi-directional data bus.

16. The process of de-serializing of claim 14 further comprising the step of:
receiving and detecting a word boundary comprised of a combination of signals on the received bit clock line and the data line.

17. A process for serializing and de-serializing, the serializing portion arranged for accepting a first data word from a computing system and sending the first data word out bit by bit, and the de-serializing portion arranged for receiving a second data word bit by bit and presenting the second data word to the computing system, the process for serializing and de-serializing comprising the step of:
serially outputting the first data word via a data line of a serial port, the means for serially outputting having a control input;
connecting a first bit clock to the control input wherein the first data bits are serially sent out, and wherein the first bit clock is synchronized to define the individual bits being sent out;
sending out the first bit clock via a bit clock line of the serial port, the first bit clock in parallel with the data bits;
serially receiving second data word bits from the data line of the serial port, the means for serially receiving data having a second control input; and
receiving a second bit clock signal from the bit clock line of the serial port, the second bit clock synchronized to define the individual bits being received, and wherein the second bit clock is connected to the second control input wherein the second data word bits are serially received.

18. The serializing and de-serializing of claim 17 further comprising the steps of:
obtaining the first data word from a bi-directional data bus of the computing system, and sending the received second data word to the computing system is via the bi-directional data bus.

19. The serializing and de-serializing of claim 17 further comprising the steps of: forming and sending a first word boundary comprised of a combination of signals on the bit clock line and the data line of the serial port; and
receiving and detecting a second word boundary comprised of a combination of signals on the bit clock line and the data line of the serial port.

20. The serializing and de-serializing of claim 17 further comprising the step of:
controlling the sending and the receiving of data and bit clock over the serial data port.
